(19) United States
(12) Patent Application Publication
(10) Pub. No.: US 2016/0276254 A1
(43) Pub. Date: Sep. 22, 2016

(54) SEMICONDUCTOR ASSEMBLY AND METHOD TO FORM THE SAME

(71) Applicant: SUMITOMO ELECTRIC DEVICE INNOVATIONS, INC., Yokohama-shi (JP)

(72) Inventor: Arata MAEKAWA, Nakakoma-gun (JP)

(73) Assignee: SUMITOMO ELECTRIC DEVICE INNOVATIONS, INC., Yokohama-shi (JP)

(21) Appl. No.: 15/071,761

(22) Filed: Mar. 16, 2016

(30) Foreign Application Priority Data
Mar. 17, 2015 (JP) 2015-053780

(51) Int. Cl. H01L 23/495; H01L 23/373; H01L 21/48

(52) U.S. Cl. CPC H01L 23/49568; H01L 21/4825; H01L 21/4839; H01L 23/3736; H01L 23/49541

(57) ABSTRACT

A semiconductor assembly is disclosed where the semiconductor assembly includes a shell with an opening, an island that shuts the opening, and terminals. The island and the terminals are originally secured by and connected to an outer support, and formed by cutting or etching a metal plate constituting a lead frame. The heat sink, which may be formed independent of the lead frame, is attached to a back surface of the island; while, a top surface of the island mounts the semiconductor element thereon. Heat generated by the semiconductor element is effectively dissipated to the heat sink through the island.

### BACKGROUND OF THE INVENTION

1. Field of the Invention

The present invention relates to a semiconductor assembly that enhances heat dissipation from a semiconductor element externally.

2. Background Arts

A Japanese Patent Application laid open No. JP-2009-170493A has disclosed a circuit board that includes a heat sink. Specifically, the circuit board disclosed therein has an opening into which the heat sink is buried. The hole has a step and the heat sink has a step tracing the step of the hole. The heat sink is positioned in a depth into the hole by the steps. The circuit board mounts a component that generates heat onto the heat sink buried into the hole.

When the heat sink, as disclosed in the prior art above, is buried into the hole of the circuit board in advance to mount a semiconductor apparatus thereon, the heat sink possibly forms a gap against the semiconductor apparatus mounted on the surface of the circuit board, which degrades the heat dissipating function from the semiconductor apparatus to the heat sink. On the other hand, when the heat sink in the top surface thereof possibly protrudes from the surface of the circuit board, the semiconductor apparatus is not securely mounted on the circuit board.

### SUMMARY OF THE INVENTION

One aspect of the preset application relates to a method to form a semiconductor assembly that provides a shell and a lead frame. The shell provides a frame and an opening surrounded by the frame. The lead frame has an island and a lead terminal. The method of the present application includes steps of: (a) closing the opening of the shell with the island of the lead frame; (b) mounting a semiconductor element on a top surface of the island within the opening of the shell; and (c) attaching a heat sink to a back surface of the island. The step of attaching the heat sink may be carried out after the step of mounting the semiconductor element, or before the step of closing the opening. That is, the heat sink is first attached to the lead frame, and then, the lead frame in the island thereof closes the opening of the shell.

Another aspect of the present application relates to a semiconductor assembly that includes a shell, a semiconductor element, an island, a lead terminal, and a heat sink. The shell has an opening into which the semiconductor element is enclosed. The island closes the opening and has a top surface that mounts the semiconductor element thereon. The lead terminal is fixed to the shell and electrically connected to the semiconductor element through an interconnection provided in the shell. The heat sink is attached to a back surface, which is opposite to the top surface, of the island.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1A is a plan view of a semiconductor assembly of an embodiment of the present application, and FIG. 1B shows a cross section taken along the ling IB-IB indicated in FIG. 1A;

FIGS. 2A and 2B are perspective drawings of a frame constituting the semiconductor assembly, where FIG. 2A views the frame from a top and FIG. 2B views the frame from a bottom thereof;

FIG. 3 schematically illustrates physical relationships between the semiconductor element, the island, and the heat sink with a circular cross section;

FIG. 4 shows a flow chart to form the semiconductor assembly according to the first embodiment of the present application;

FIG. 5A shows a step to prepare a shell and a lead frame, and FIG. 5B shows cross sections of the shell and the lead frame, which are taken along the line VB-VB indicated in FIG. 5A;

FIG. 6A shows a step to attach the lead frame to the shell, and FIG. 6B shows a cross section thereof taken along the line VIB-VIB denoted in FIG. 6A;

FIG. 7A shows a step to mount the semiconductor element on the top surface of the island, and FIG. 7B shows a cross section thereof taken along the line VIIB-VIIB appearing in FIG. 7A;

FIG. 8A shows a step to wire-bond the semiconductor element to the interconnection on the frame, and FIG. 8B shows a cross section thereof taken along the line VIIIB-VIIIB appearing in FIG. 8A;

FIG. 9A shows a step of sealing the opening of the shell by a lid, and FIG. 9B shows a cross section thereof taken along the line IXB-IXB illustrated in FIG. 9A;

FIG. 10A shows a step of attaching the heat sink to the back surface of the island, and FIG. 10B shows a cross section thereof taken along the line XB-XB indicated in FIG. 10A;

FIG. 11A shows a step of preparing the lead frame to which the heat sink is to be attached, and FIG. 11B shows cross section of the lead frame taken along the line XIB-XIB appearing in FIG. 11A;

FIG. 12A shows a step of forming a resist that indicates a position on the island to which the heat sink is to be attached, and FIG. 12B shows a cross section of the lead frame taken along the line XIIB-XIIB indicated in FIG. 12A;

FIG. 13A is a plan view showing a process to attach the heat sink onto the island, and FIG. 13B shows a cross section thereof taken along the lone XIIIB-XIIIB appearing on FIG. 13A;

FIG. 14 shows a cross section of a board assembly that includes the semiconductor assembly mounted on the circuit board;

FIG. 15A is a plan view of a semiconductor assembly according to the second embodiment of the present invention, and FIG. 15B shows a cross section taken along the line XVB-XVB indicated in FIG. 15A;

FIG. 16A is a plan view showing a semiconductor assembly according to the third embodiment of the present application, and FIG. 16B shows a cross section thereof taken along the line XVIB-XVIB indicated in FIG. 16A; and

FIG. 17A is a plan view showing a semiconductor assembly according to the fourth embodiment of the present application, and FIG. 17B shows a cross section taken along the line XVIIB-XVIIB indicated in FIG. 17A.

### DESCRIPTION OF EMBODIMENTS

Next, some examples according to the present invention will be described as referring to accompanying drawings. In the description of the drawings, numerals or symbols same with or similar to each other will refer to elements same with or similar to each other without duplicated explanations.

### First Embodiment

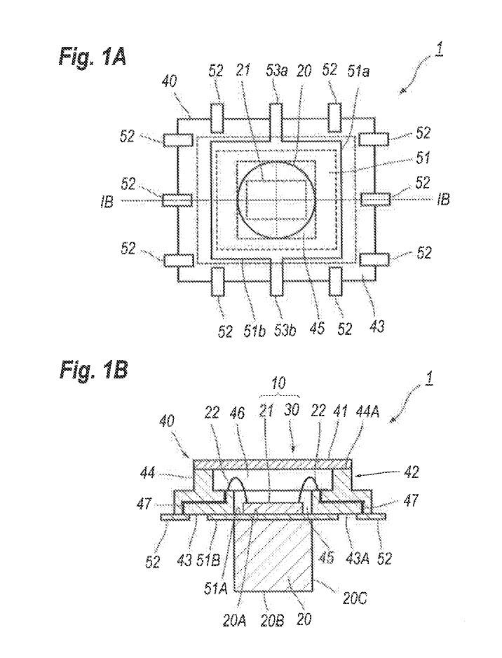

FIG. 1A schematically illustrates a plan view of a semiconductor assembly 1 according to the first embodiment of the present application, and FIG. 1B shows a cross section of the semiconductor assembly 1 taken along a line IB-IB indicated in FIG. 1A. The semiconductor assembly 1 comprises a semiconductor device 10 and a heat sink 20, where the semiconductor device 10 includes a semiconductor element 21 and a package 30 that encloses the semiconductor element 21 therein. The package 30 comprises a shell 40 and a lid 41. In the present embodiment of the semiconductor assembly 1, the semiconductor element 21 may be a transistor capable of outputting large power at high frequencies, which is often called as a power transistor, in particular, a power transistor primarily made of nitride semiconductor materials.

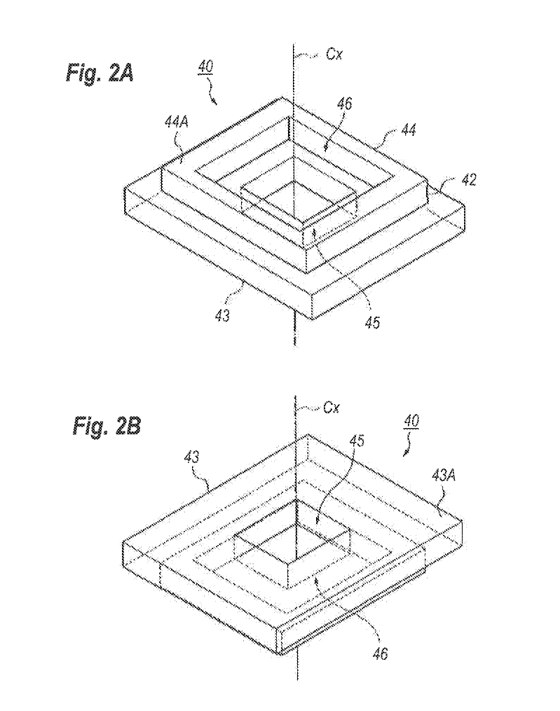

FIGS. 2A and 2B show perspective views of the shell 40, where FIG. 2A views the shell 40 from a top thereof and FIG. 2B views the shell 40 from a bottom. As shown in FIGS. 2A and 2B, the shell 40 provides a frame 42 including a lower frame 43 and a upper frame 44 that is stacked on the lower frame 43 along an axis Cx. The lower frame 43 and the upper frame 44 provide respective openings, namely, a lower opening 45 in the lower frame 43 and an upper opening 46 in the upper frame 44. The frame 42 may be made of electrically insulating material, typically, ceramics. When the frame 42 is made of ceramics, the lower frame 43 and the upper frame 44 may be formed separately, then, brazed to each other.

The lower frame 43 provides a bottom surface 43A to which an island 51 and lead terminals 52 are attached such that the island 51 and the lead terminals 52 are leveled in a plane and the island 51 fully covers the lower opening 45. The upper frame 44 provides a top surface 44A onto which a lid 41 is attached so as to fully cover the upper opening 46. Thus, the frame 40, the island 51, and the lid 41 may air-tightly enclose the semiconductor element 21 set within the package 30. The frame 42, as described above, may be made of ceramics, but, the frame 42 may be made of metal, resin, and so on.

Referring to FIG. 1 again, the semiconductor device 10 of the present embodiment provides the island 51 and a plurality of lead terminals, where the latter includes lead terminals 52 for carrying high frequency signals and/or biases and other lead terminals, 53a and 53h, for the ground. The lower frame 43, exactly, the bottom surface 43A of the lower frame 43 fixes the island 51 and the lead terminals, 52 to 53b, thereto. Specifically, the lead terminals 52 are arranged apart from edges, 51a and 51b, of the island 51 as surrounding the island 51. The ground terminals, 53a and 53h, are connected to the island 51. These terminals, 52 to 53b, may be brazed to the lower frame 43 in respective metalized patterns thereof. The island 51 and the terminals, 52 to 53b, may be made of copper (Cu) and/or alloy containing iron (Fe), nickel (Ni), and cobalt (Co), which is often called as Kovar™.

The island 51, which may be a metal plate, provides a top surface 51A and a back surface 51B. The top surface 51A mounts the semiconductor element 21 thereon. Bonding wires 22 may electrically connect the semiconductor element 21 to the interconnections 47 that are electrically connected to the lead terminals 52. Thus, the semiconductor element 21 may be electrically connected to an external through the lead terminals 52, the interconnections 47, and the bonding wires 22.

The heat sink 20, which may be fixed to the hack surface 51B of the island 51 by, for instance, eutectic solder such as AuSn, provides a top surface 20A and a bottom surface 20B. In the present embodiment shown in FIGS. 1A and 1B, the top surface 20A of the heat sink 20 is in contact to the back surface 51B of the island 51. The heat sink 20 may be made of copper (Cu) and/or composite metal of copper/molybdenum/copper (Cu—Mo—Cu). The heat sink 20 of the present embodiment has a column shape having sides 20C connecting the top surface 20A to the back surface 20B and capable of being inserted within a hole provided in a circuit board on which the semiconductor assembly 1 is to be mounted. The heat sink 20 may have a cross section of a circle, a rectangle, a square and/or an oval.

In the semiconductor assembly 1, the island 51 mounts the semiconductor element 21 on the top surface 51A thereof, while, the back surface 51B thereof is in contact to the heat sink 20. This arrangement of the semiconductor element 21, the island 51, and the heat sink 20 may effectively conduct heat generated by the semiconductor element 21 to the heat sink 20. Moreover, the heat sink 20 in the bottom surface 20A thereof may be in contact to an external heat sink provided under the circuit board on which the semiconductor assembly 1 is to be mounted by piercing the hole formed in the circuit board. Thus, the heat dissipation from the semiconductor element 21 may be enhanced in the present arrangement of the semiconductor assembly 1.

The heat sink 20 of the embodiment may have dimensions corresponding to a thickness of the circuit board and/or a diameter of the hole formed in the circuit board. Securing the semiconductor assembly 1 on the circuit board, specifically, fixing the terminals, 52 to 53b, to metal patterns provided on the circuit board, the heat sink 20 may be prohibited from being inserted into the hole excessively, which may prevent the semiconductor element 21 from being apart from the heat sink 20. Also, setting lateral sizes of the heat sink 20 to be smaller than sizes of the hole, the heat sink 20 may be fully inserted within the hole such that the top surface 20A of the heat sink 20 does not protrude from the top surface of the circuit board.

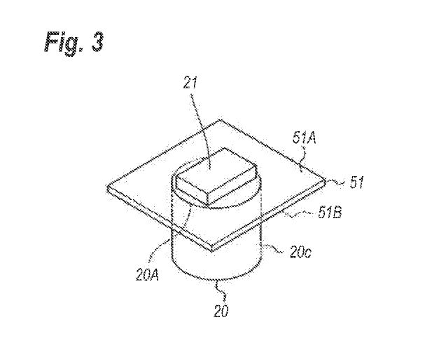

FIG. 3 schematically illustrates physical relationships between the semiconductor element 21, the island 51, and the heat sink 20 with a circular cross section. The heat sink 20 illustrated in FIG. 3 has a column shape with the circular cross section; however, the heat sink 20 may have other types with various cross sections. For instance, a heat sink with a square, a rectangular, and/or, occasionally a triangular cross section may be applicable to the semiconductor assembly 1. The semiconductor element 21 is preferably mounted within an area 20A on the top surface of the island 51, where the area 20A reflects the cross section of the heat sink 20. This arrangement of the semiconductor element 21 and the area 20A may secure a contact area of the heat sink 20 to the island 51 greater than a contact area of the semiconductor element 21 to the island 51, which makes it possible for the heat generated in the semiconductor element 21 to conduct beneath as spreading therefrom.

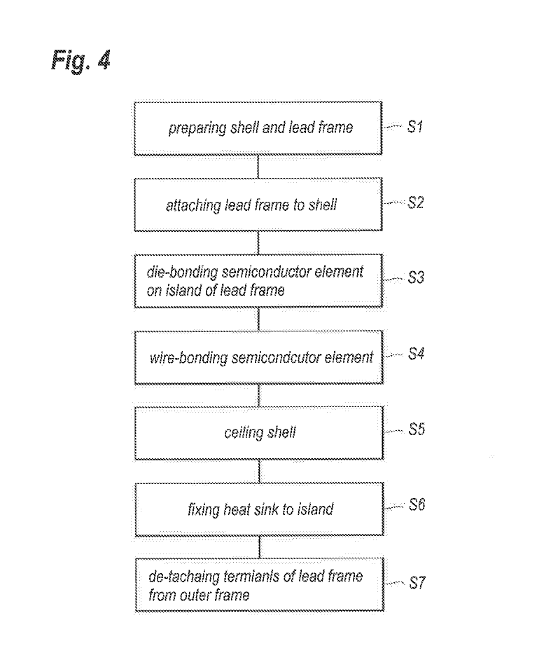

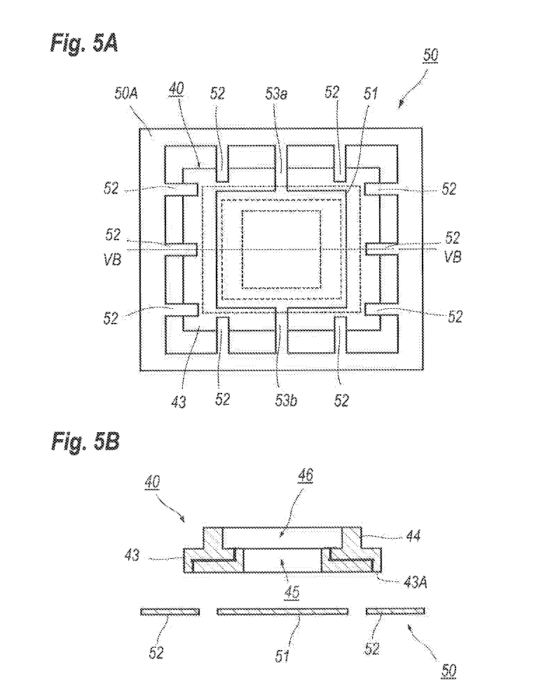

FIG. 4 shows a flow chart to form the semiconductor assembly according to the first embodiment of the present application; and FIGS. 5A to 10A are plan views and FIGS. 5B to 10B are cross sections of the semiconductor assembly 1 taken along respective lines indicated in FIGS. 5A to 10A during the respective process shown in FIG. 4.

As shown in FIGS. 5A and 5B, step S1 prepares a shell 40 and a lead frame 50, where the shell 40 includes a frame 42 that comprises a lower frame 43 with a lower opening 45 and an upper frame 44 with an upper opening 46. The lead frame 50 includes an island 51 and terminals, 52, 53a and 53h, where the terminals, 52 to 53b, are secured by an outer support 50A. The lead frame 50 may be formed by stamping or etching a metal plate. Because the metal plate for the lead frame 50 is an even plate, the island 51 and the terminals, 52 to 53h, have an even level. The island 51, which is connected to the outer support 50A by the terminals, 53a and 53b, will mount the semiconductor element 21 thereon.

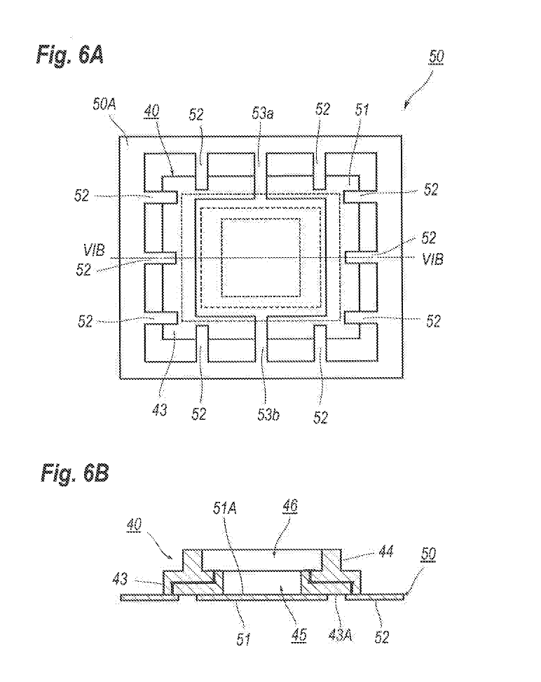

Step S2 attaches the lead frame 50 to the shell 40, as shown in FIGS. 6A and 6B. The shell 40 of the present embodiment has the shape shown in FIGS. 2A and 2B. The top surface 51A of the island 51, and the terminals, 52 to 53b, are attached to the lower frame 43, which means that the island 51 covers or closes the lower opening 45 in the lower frame 43. That is, the island 51 becomes a bottom surface of the lower opening 45.

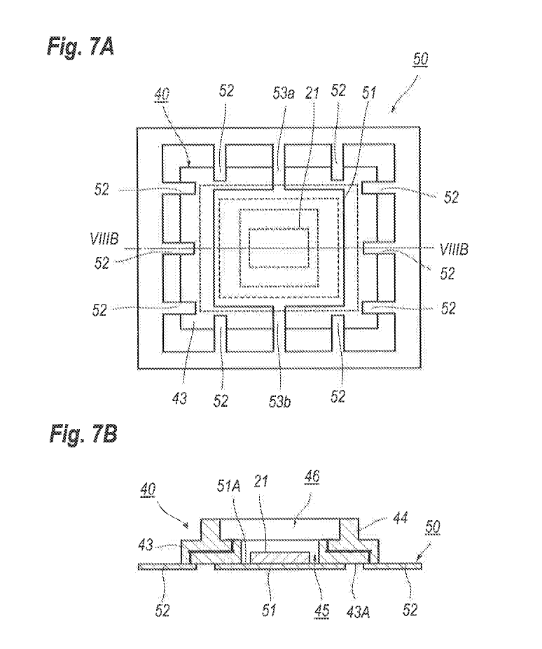

The step S3 die-mounts the semiconductor element 21 on the top surface 51A of the island 51, as shown in FIGS. 7A and 713. An eutectic solder, for instance gold tin (AuSn), an electrically conductive resin containing silver (Ag) or gold (Au), and so on may attach the semiconductor element 21 on the island 51. When the electrically conductive resin is applied, a subsequent heat treatment may vaporize organic solvent contained in the resin.

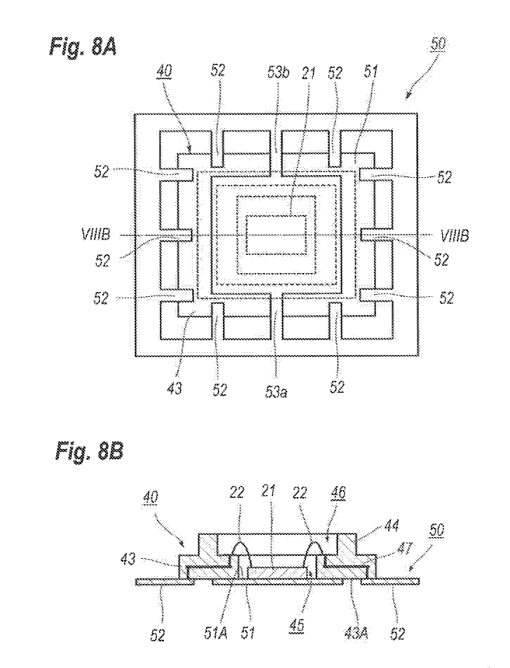

The step S4 carries the wire-bonding from the semiconductor element 21 to the interconnection 47 exposed on an inside surface of the lower frame 43 by bonding wires 22 made of gold (Au), as shown in FIGS. 8A and 8B. Because the interconnections 47 continue to the lead terminals 52, the semiconductor element 21 may be connected to the lead terminals 52 through the bonding wires 22 and the interconnections 47.

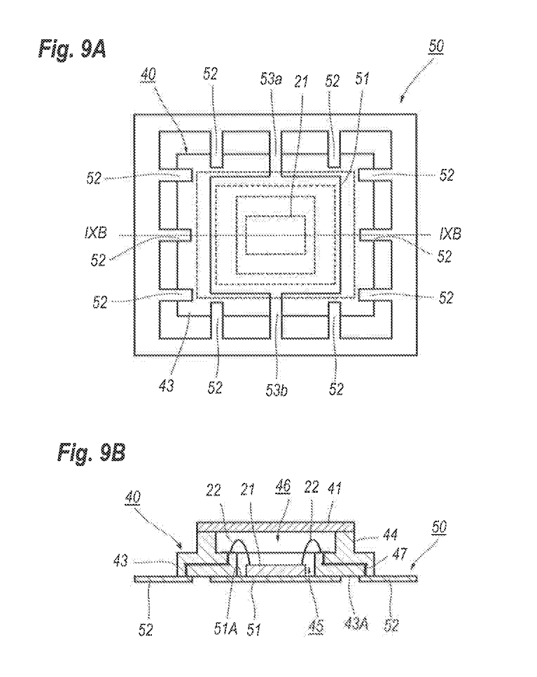

The step S5 seals the upper opening 46 and the lower opening 45 by a lid. 41 as illustrated in FIGS. 9A and 9B. The semiconductor element 21 may be air-tightly sealed by the lid 41 within the space of the package 30 formed by the shell 40, the island 51, and the lid 41. The lid 41 is fixed on the top surface 44A of the upper frame 44 by the seam sealing using eutectic solder of AuSn, or by adhesive.

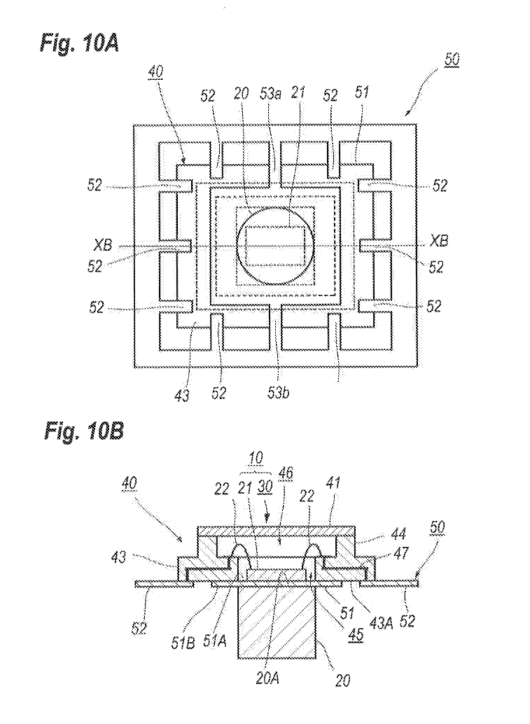

The step S6 attaches the heat sink 20 to the back surface 51B of the island 51, as illustrated in FIGS. 10A and 10B. The top surface 20A of the heat sink 20 is soldered to the back surface 51B of the island 51 by eutectic solder of AuSn.

The step S7 detaches the terminals, 52 to 53b, from the outer support 50A by a lead cutter, and/or, by etching excess parts of the lead frame 50. Thus, the process for producing the semiconductor assembly 1 is completed. Although the process thus described attaches the heat sink 20 to the island 51 after the semiconductor element 21 is die-mounted on the island 51. However, the process may attach the heat sink 20 to the island 51 before the island 51 die-mounts the semiconductor element 21 thereon.

According to the process for producing the semiconductor assembly 1 of the present embodiment, the lead frame 50 having the island 51 and the terminals, 52 to 53b, are attached to the back surface 43A of the lower frame 43. The island 51 of the lead frame 51 die-mounts the semiconductor element 21 on the top surface 51A thereof, while; attaches the heat sink 20 in the back surface 51B. Moreover, the island 51 and the terminals, 52 to 53b, have a common virtual plane, that is, the island 51 and the terminals, 52 to 53b, are formed in an even plane.

The process shown in FIG. 4 may further provide to prepare various types of the heat sink 20. That is, the process may select dimensions of the heat sink 20. Depending on amount of the heat generated by the semiconductor element 21 and the heat dissipating function necessary to the semiconductor assembly 1, the size and the material of the heat sink 20 may be determined. Also, a thickness of solder that fixes the heat sink 20 to the back surface 51B of the island 51 and sizes of the hole in the circuit board into which the heat sink 20 is to be inserted may determine the size of the heat sink 20.

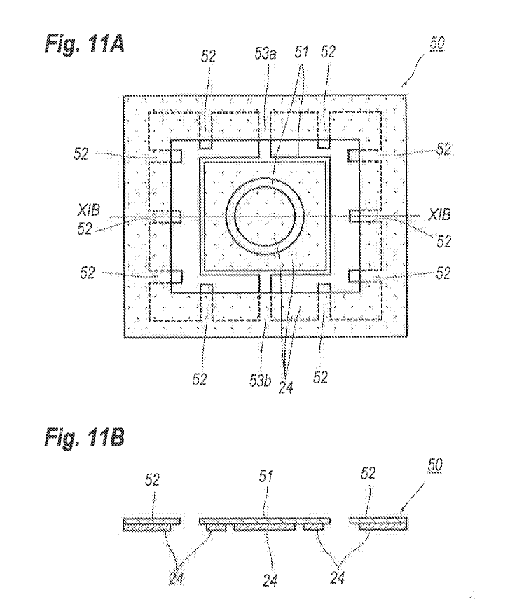

Next, a process for fixing the heat sink 20 to the back surface 51B of the island 51 will be described in detail. FIGS. 11A to 13B show procedures to form an intermediate product of the semiconductor assembly 1, where FIGS. 11A to 13A are plan views of the intermediate product, while, FIGS. 11B to 13B show cross sections of the intermediate product taken along the lines indicated in FIGS. 11A to 13A.

As illustrated in FIGS. 11A and 11B, the lead frame 50 is partially covered with a mask 24 in the back surface thereof. Specifically, portions of a center circle and peripheral squares of the back surface 51B of the island 51, and respective root portions of the terminals, 52 to 53b, are covered with the mask 24. The back surface 51B of the island 51 is covered with the mask 24 as leaving peripheries thereof along respective edges and a center doughnut. The center doughnut indicates the position to which the heat sink 20 is to be attached and has an inner diameter corresponding to the diameter of the heat sink 20.

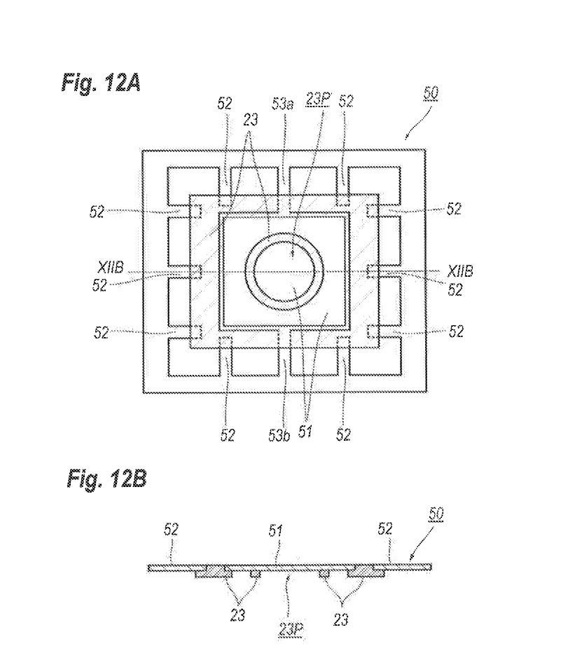

Then, as illustrated in FIGS. 12A and 12B, the resist 23 is formed using the mask 24. That is, the resist 23 has patterns in positions not covered with the mask 24. Specifically, the resist 23 leaves a center circle 23P surrounded by the doughnut pattern 23, where the outer shape of the center circle 23P fully covers the top surface 20A of the heat sink 20. The resist 23 may be a photosensitive solder resist. That mask 24 is removed after the formation of the resist 23.

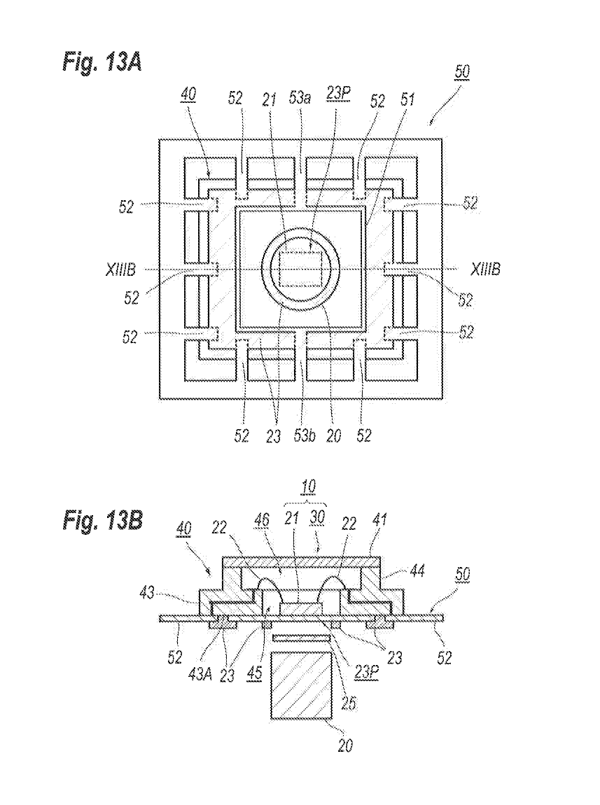

As illustrated in FIGS. 13A and 13B, a solder 25 is placed onto the back surface 51B of the island 51, where the solder 25 has an outer shape corresponding to the opening 23P of the resist 23. In the present embodiment, the solder 25 may be made of alloy of tin (Sn) and lead (Pb), SnPb, or eutectic solder of gold (Au) tin (Sn), AnSn. Raising a temperature of the island 51 higher than a melting temperature of the solder 25, the heat sink 20 is placed onto the melted solder 25 in the area 23P so as to attach the top surface 20A to the melted solder 25. Because the melted solder 25 has a large surface tension, the heat sink 20 placed onto the melted solder 25 may move so as to reduce the surface tension, that is, the position of the heat sink 20 may be automatically determined so as to reduce the surface tension of the solder 25. Positioning the heat sink 20, the solder 25 is solidified by cooling the temperature of the island 51 down. The peripheral of the opening 23P, namely, the edges of the solder 25 is inside of the peripheral of the top surface 20A of the heat sink 20. According to the process for the semiconductor assembly 1 thus described, the heat sink 20 may be automatically positioned within the opening 23P in the back surface 51B of the island 51.

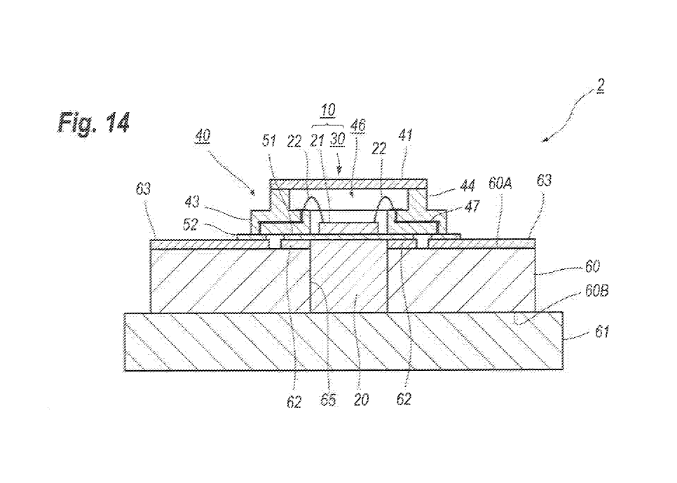

FIG. 14 schematically shows a cross section of a board assembly 2 including the semiconductor assembly 1 thus described and a circuit board 60 mounting the semiconductor assembly 1 thereon. The circuit board 60 may be a type of Teflon™ substrate. The circuit board 60 may accompany with a heat sink 61 in a back surface 60B thereof.

The circuit board 60 includes a primary surface 60A and the back surface 60B. The circuit board 60 also provides a hole 65 extending from the primary surface 60A to the back surface 60B. The primary surface 60A provides interconnections, 62 and 63, where the former interconnection 62 is connected to the island 51 of the semiconductor assembly 1, while, the latter interconnection 63 is connected to the lead terminals 52. The back surface 60B provides the heat sink 61. The hole 65 receives the heat sink 20 of the semiconductor assembly 1. That is, inserting the heat sink 20 of the semiconductor assembly 1 into the hole 65 such that the heat sink 20 is in contact to the heat sink 61 and the island 51 and the terminals 52 are bonded to the interconnections, 62 and 63, the board assembly 2 may be formed.

In the board assembly 2 of the present embodiment that includes the semiconductor assembly 1 and the circuit board 60, the heat sink 20 of the semiconductor assembly 1 passes through the hole 65 of the circuit board 60 and is in contact to the heat sink 61 placed beneath the circuit board 60 such that the back surface 60B of the circuit board 60 is in contact thereto. The heat sink 20 may dissipate heat generated by the semiconductor element 21 effectively to the heat sink 61; accordingly, the semiconductor element 20 does not raise an operating temperature thereof. Also, the island 51 and the lead terminals 52 may be reliably connected to the interconnections, 62 and 63, on the surface 60A of the circuit board 60 as being secured with the shell 40 of the package 30. As already described, the island 51 and the terminals, 52 to 53b, are originally secured by the outer support 50A, where those island 51, the terminals, 52 to 53b, and the outer support 50A are formed by cutting or etching a metal plate. That is, the island 51, the terminals, 52 to 53b, and the outer support 50A have the arrangement of a lead frame. The back surface of the island 51 has a level common to or equal to the level of the terminals, 52 to 53b. Accordingly, setting the semiconductor assembly 1 on the circuit board 60, the island 51 and the terminals, 52 to 53h, may be securely and reliably connected to the interconnections, 62 and 63, of the top surface 60A of the circuit board 60. When the semiconductor assembly 1 outputs high frequency signals with extremely high power; the semiconductor assembly 1 is strongly requested to be stable in the ground pattern thereof, which is connected to the island 51. Therefore, the island 51 is necessary to be stably and reliably in contact to the ground pattern on the circuit board 60. The arrangement of the semiconductor assembly 1 that provides the island 51 and the terminals, 52 to 53b, originally formed by a lead frame may stabilize the ground pattern.

### Second Embodiment

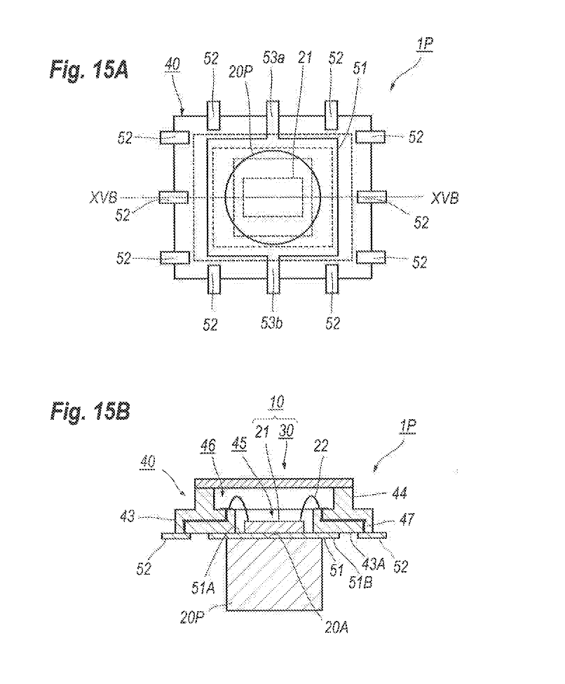

FIG. 15A is a plan view of a semiconductor assembly 1P according to the second embodiment of the present invention, and FIG. 15B shows a cross section taken along the line XVB-XVB indicated in FIG. 15A. The semiconductor assembly 1P shown in FIGS. 15A and 15B has a feature concerning to the heat sink 20P thereof. That is, the heat sink 20P of the present embodiment has a cross section greater than the lower opening 45 of the lower frame 43. The island 51, same with that of the aforementioned embodiment, is in contact to the bottom 43A of the lower frame 43 and mounts the semiconductor element 21 thereon. The semiconductor assembly 1P has arrangements same with those of the first embodiment except for the size of the heat sink 20P.

According to the semiconductor assembly 1P of the second embodiment, the heat sink 20P, which has the size greater than the size of the lower opening 45, is supported by not only the island 51 but the shell 40, namely, the lower frame 43. This arrangement may suppress deformations caused by an attachment of the heat sink 20P to the island 51. The heat sink 20P may be securely and reliably supported to the shell 40 and the island 51 compared with the arrangement of the first embodiment.

### Third Embodiment

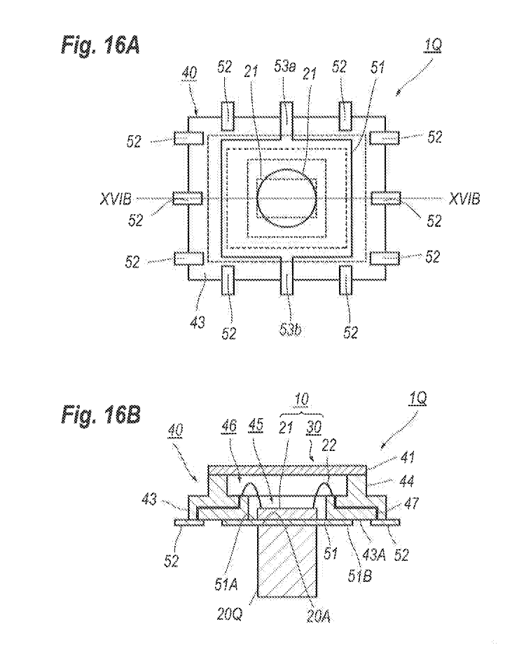

FIG. 16A is a plan view showing a semiconductor assembly 1Q according to the third embodiment of the present application, and FIG. 16B shows a cross section thereof taken along the line XVIB-XVIB indicated in FIG. 16A. A feature of the semiconductor assembly 1Q of the present embodiment is that the semiconductor assembly 1Q provides a heat sink 20Q having a cross section, or the top surface 20A thereof smaller than the size of the lower opening 45. This arrangement of the heat sink 20Q with respect to the semiconductor element 21 makes it possible to assemble the heat sink 20Q in a position reflecting a position of the semiconductor element 21 on the island 51. That is, the position of the heat sink 20Q in the island 51 may be optional depending on the position of the semiconductor element 21 within the lower opening 45.

### Fourth Embodiment

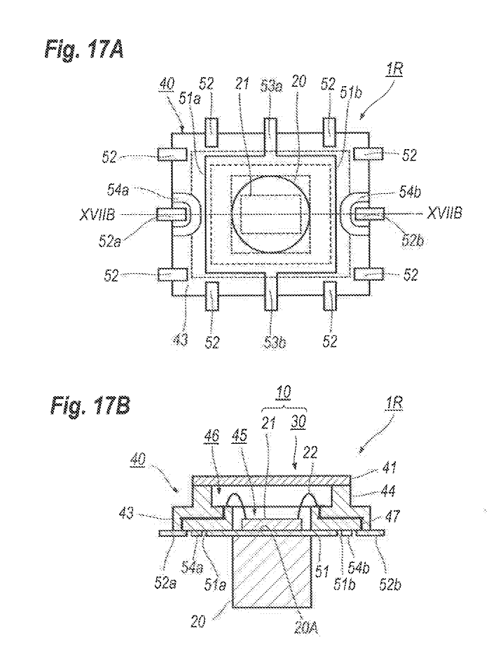

FIG. 17A is a plan view showing still another semiconductor assembly 1R according to the fourth embodiment of the present application, and FIG. 17B shows a cross section taken along the line XVIIB-XVIIB indicated in FIG. 17A. One of features of the semiconductor assembly 1R of the present embodiment is that the terminals, 52a and 52b, which are arranged along an axis of the semiconductor assembly 1R facing to each other as putting the island 51 therebetween, accompany with respective ground patterns, 54a and 54h. The ground patterns, 54a and 54b, pass between the island 51 and the respective terminals, 52a and 52b; and surround the terminals, 52a and 52b as forming gaps against the terminals, 52a and 52b. Because the ground patterns, 54a and 54b, are connected to the ground on the circuit board 60, the semiconductor assembly 1R may be further stabilized in the ground thereof, which may suppress the degradation of high frequency performance of the semiconductor assembly 1R.

The foregoing descriptions of specific examples of the present invention have been presented for purposes of illustration and description. They are not intended to be exhaustive or to limit the invention to the precise forms disclosed, and obviously many modifications and variations are possible in light of the above teaching. The examples were chosen and described in order to best explain the principles of the invention and its practical application, thereby to enable others skilled in the art to best utilize the invention and various examples with various modifications as are suited to the particular use contemplated. It is intended that the scope of the invention be defined by the claims appended hereto and their equivalents.

What is claimed is:

1. A method to form a semiconductor assembly that provides a shell and a lead frame, the shell provides a frame and an opening surrounded by the frame, the lead frame having an island and a lead terminal, comprising steps of:
closing the opening of the shell with the island of the lead frame;
mounting a semiconductor element on a top surface of the island within the opening of the shell; and
attaching a heat sink to a back surface of the island.

2. The method of claim 1,
wherein the step of closing the opening includes a step of brazing the island and the lead terminal to the shell.

3. The method of claim 2,
further including steps of, after the step of brazing the island and the lead terminal to the shell but before the step of attaching the heat sink to the island,
forming a pattern surrounding an area to which the heat sink is to be attached.

4. The method of claim 3,
wherein the step of attaching the heat sink includes steps of:
placing solder onto the area;
melting the solder by raising a temperature of the island;
placing the heat sink onto the melted solder; and
cooling the temperature of the island down to a temperature to solidify the solder.

5. The method of claim 1,
further including steps of, after the step of attaching the heat sink, ceiling the opening of the shell and detaching the lead terminal from an outer support of the lead frame.

6. The method of claim 1,
further including a step of wire-bonding the semiconductor element to interconnections provided in the shell, the interconnections being electrically connected to the lead terminal.

7. A method to form a semiconductor assembly that provides a shell and a lead frame, the shell provides a frame and an opening surrounded by the frame, the lead frame having a island and a lead terminal, comprising steps of:
attaching a heat sink to a back surface of the island,
closing the opening of the shell with the island of the lead frame; and
mounting a semiconductor element on a top surface of the island within the opening of the shell.

8. A semiconductor assembly, comprising:
a shell having an opening;
a semiconductor element enclosed within the opening of the shell;
an island that closes the opening and mounts the semiconductor element on a top surface thereof;
a lead terminal fixed to the shell, the lead terminal being electrically connected to the semiconductor element through an interconnection provided in the shell; and
a heat sink attached to the island in a back surface opposite to the top surface thereof.

9. The semiconductor assembly of claim 8,
wherein the heat sink has a cross section greater than a cross section of the semiconductor element, and
wherein the semiconductor element is fully projected on the heat sink.

10. The semiconductor assembly of claim 9,
wherein the semiconductor element in outer edges thereof is fully within outer edges of the heat sink.

11. The semiconductor assembly of claim 8,
wherein the heat sink has a cross section greater than a cross section of the opening.

12. The semiconductor assembly of claim 8,
wherein the shell has a conductive pattern surrounding the

[symbol]

13. The semiconductor assembly of claim 12,
wherein the conductive pattern passes between the island and the lead terminal.

14. The semiconductor assembly of claim 8,
wherein the heat sink is made of metal containing copper (Cu).

15. The semiconductor assembly of claim 14,
wherein the heat sink is made of composite metal of copper (Cu), molybdenum (Mo), and copper (Cu).
